(19) United States
(12) Patent Application Publication
(10) Pub. No.: US 2019/0006142 A1
(43) Pub. Date: Jan. 3, 2019

(54) ANTENNA ARRANGEMENT

(71) Applicant: Ampass-Explorer Corp., Road Town (VG)

(72) Inventor: Siegfried Stauber, Zurich (CH)

(21) Appl. No.: 16/020,127

(22) Filed: Jun. 27, 2018

Related U.S. Application Data
(63) Continuation-in-part of application No. 14/736,673, filed on Jun. 11, 2015, now abandoned.

(30) Foreign Application Priority Data
Jun. 26, 2014 (EP) 14174557.0

(51) Int. Cl. H01J 37/08; G01V 3/08; H01Q 1/38

(52) U.S. Cl. CPC H01J 37/08; H01Q 1/38; G01V 3/08

(57) ABSTRACT

An antenna arrangement on a printed circuit board with at least two magnetic rings and a rectangular ring cross section and lateral magnetic ring surfaces with opposite polarity formed thereby wherein the magnetic ring surfaces are arranged on the printed circuit board with a distance from one another using a spacer, wherein the opposite polarities of the magnetic ring surfaces are oriented towards each other and the central bore holes of the magnetic ring form a pass through bore hole through a bore hole in the spacer. This antenna arrangement is configured for a material detector device which detecting predetermined materials over a distance. The antenna arrangement is infinitely expandable in its operation by increasing the number of the magnetic rings and of the respective spacers. Being compact the antenna arrangement easily integrates into existing devices and can be produced in a cost effective manner.

### RELATED APPLICATIONS

This application is a continuation-in-part which claims priority from, and incorporates by reference, U.S. application Ser. No. 14/736,673, filed Jun. 11, 2015.

### FIELD OF THE INVENTION

The invention relates to an improved antenna arrangement for a material detector device for detecting objects made from a predetermined material by emitting an ion beam and receiving a returning ion beam including a printed circuit board at least for receiving electronic circuits and components and an antenna and electrical connecting conductors to the antenna.

### BACKGROUND OF THE INVENTION

DE 10 329 335 discloses a material detector device which is used for detecting objects of a predetermined material in that an electromagnetic signal configured as an ion beam is emitted and the returning signal is detected. This document also describes a transmitting and receiving antenna used for this purpose which is arranged on a printed circuit board which is used at least for receiving electronic circuits and components and electronic connecting conductors to the antenna. A material detector device which facilitates detecting materials commercially available at AMPASSMETER GmbH, Handwerkerhof 1, D-54338, Schweich.

### BRIEF SUMMARY OF THE INVENTION

Thus, it is an object of the present invention to propose an improved antenna arrangement which is configured much smaller than the known antenna and thus facilitates installation in other mobile devices in order to provide additional material detection with these devices.

This object is achieved according to the invention by an improved antenna arrangement with features of the independent claim. Additional advantageous embodiments can be derived from the dependent claims.

Another object of the invention is to provide an antenna arrangement for a material detecting device made from a predetermined material by emitting an emitted signal and receiving a returning signal reflected by predetermined material where properties of the predetermined material cause a reflection of the emitted signal to form the returning signal, the antenna arrangement including a printed circuit board including an antenna circuit and an antenna. The antenna emits the emitted signal and receives the returning signal, and the antenna circuit generates a transmission signal that is emitted by the antenna as the emitted signal and processes the returning signal from the antenna. The antenna includes at least two magnetic rings, the at least two magnetic rings each have a rectangular ring cross section and lateral magnetic ring surfaces having opposite polarity forming electrodes on the printed circuit board by at least one spacer including a bore hole at a distance from one another. Opposite polarities of the magnetic ring surfaces are oriented towards one another and bore holes of the magnetic rings in combination with the bore hole in the at least one spacer form a pass through bore hole. The magnetic rings are connected to the electronic antenna circuit arranged on the printed circuit board. The antenna circuit applies a repeating triangular or saw tooth signal with a pause between the signals to the magnetic rings, and an amplitude and a frequency of the triangular or saw tooth signal with the pause is adjustable through the antenna circuit. The bore hole in the at least one spacer may be aligned with the bore holes of the at least two magnetic rings. Two adjacent magnetic rings of the at least two magnetic rings may sandwich the printed circuit board, and the printed circuit board may be the spacer for the two adjacent magnetic rings. The returning signal may be received while the repeating triangular or saw tooth signal with a pause between the signals is pausing.

According to the invention the antenna arrangement includes at least two magnetic rings with a rectangular ring cross section, wherein the magnetic rings are arranged by a spacer at a distance from one another on the printed circuit board. The rectangular ring cross sections form lateral magnetic ring surfaces with opposite polarity, wherein the opposite polarities of the magnetic ring surfaces are oriented towards each other and the central bore holes of the magnetic rings form a pass through bore hole through a bore hole in the spacer. The magnetic rings can thus be arranged on both sides of the printed circuit board, so that the printed circuit board is used as a spacer and includes a bore hole so that a pass through bore hole through the two magnetic rings and the printed circuit broad is provided. Another option is to arrange the magnetic rings with a spacer with pass through bore hole on a side of the printed circuit board so that the pass through bore hole formed by the magnetic rings and the spacer either extends perpendicular or essentially parallel to the printed circuit board. As a matter of principle additional magnetic rings that are separated by spacers can adjoin each magnetic ring, wherein furthermore the magnetic rings are oriented towards each other with magnetic ring surfaces with opposite polarity.

The antenna formed by the magnetic rings and the spacer is connected to an electronic circuit so that applying a saw tooth voltage with a pause generates oxygen or nitrogen ions from air about the magnetic rings and in an interior of the magnetic rings. Through the magnetic rings and the spacers arranged there between the ions are accelerated and ejected out of the pass through bore hole. Plural offset magnetic rings provide a higher velocity of the cations until a resonance avalanche is generated corresponding to the ionization energy steps. This causes a cation beam in the direction south pole-north pole for oxygen and nitrogen cations and versa an anion beam for oxygen and nitrogen anions. Generally speaking: an acceleration path for oxygen and nitrogen ions. Since the cations are smaller and lighter they are accelerated more strongly and therefore also have improved material permeability so that they collide with air molecules very little or not at all. Thus the cations are advantageously used. Through the frequency of the triangular signal and the amplitude the respective cations are tuned to the material to be detected. In fact mostly oxygen cations are used since they are ionized from air more quickly due to smaller bonding forces. When the oxygen cations impact respective cations on the predetermined material a reflection is provided which can be measured and processed in the transmission brakes as an electrical signal in the electronic circuit when returning to the magnets. The display is provided optically and acoustically. The magnetic ring arrangement acts similar to an ion source when accelerating the cations and anions. Interference signals are suppressed in a known manner by using a differential amplifier in the electronic circuit.

In order to configure the pass through space as advantageous as possible for forming and accelerating ions, in particular the cations, in this portion according to an advantageous embodiment of the invention the bore hole in the spacer is aligned with the bore holes of the magnetic rings.

According to a particularly preferred embodiment of the invention the spacer for a first and a second magnetic ring is the printed circuit board so that at least one magnetic ring is arranged on each side of the printed circuit board in a space saving manner wherein the printed circuit board includes a respective pass through bore hole. As stated supra the arrangement can be expanded by additional spacers and magnetic rings.

According to another advantageous embodiment a circuit is arranged on the printed circuit board, wherein the circuit emits a saw tooth signal or a triangular signal through the magnetic rings, wherein a cycle of the saw tooth signal also includes a transmission pause and wherein the circuit receives the return signal in a transmission pause.

Thus, the antenna arrangement according to the invention facilitates emitting and receiving an ion beam and processing it within a minimal space. When the entire unit is configured accordingly together with the antenna arrangement the pass through bore hole can be simultaneously used for determining the direction of the seeked material, for example with a laser pointer beam or laser diode beam. For inaccessible locations, e.g. medical technology also a light wave conductor (diameter 1 mm) can be inserted through the pass through bore hole in order to receive information from another end of the light wave conductor. Due to its small size the antenna arrangement can also be integrated into a mobile telephone so that detecting materials can also be provided therewith.

The antenna arrangement that is to be used for a material detector arrangement is commercially available and does not have to be recreated. It is furthermore described in the application in detail that a saw tooth voltage with pauses is applied whose frequency has to correspond to the material to be detected. In fact the frequency has to correspond very closely to the inherent frequency of the material (+/−0.02 Hz) so that the reflection can be provided at the surface of the crystal grid of the respective material. It is well known that each crystal grid has a fundamental oscillation. This is a resonance oscillation at which all atoms or ions of one type oscillate in phase. When an electromagnetic wave impacts the crystal and a frequency of the electromagnetic wave coincides with the frequency of the resonance oscillation this wave is absorbed in the crystal to a particularly large extent but also reflected at a surface of the crystal to a particularly large extent. This is the reason why the voltage generating the ions has to have a predetermined frequency.

The applied voltage generates an electric field between the magnets as an electrode and the earth so that ions are accelerated by the electrical field. From electron and ion optics it is known to apply an acceleration voltage between the electrodes in order to impart kinetic energy to the electrically charged particles. The electrical field strength between the electrodes and thus the acceleration of the particles are a function of the distance of the electrodes. Particles with a charge q are provided with the electrical energy Eₑₗ=qU when an acceleration voltage U is applied. For non-relativistic velocities (v<<c) the kinetic energy of a particle with the mass m is approximately Eₖᵢₙ≈½ mv². Thus, a velocity v according to the following equation is obtained: v=(2 U q/m)^{-1/2}

The specific charge of an electron is for example −1.76×10¹¹ C/kg so that an acceleration voltage of −2.84 Volt suffices for a velocity of 1000 km/s. In the instant case oxygen ions are accelerated so that a velocity for the ions is computed at approximately of 380 m/s in view of the effective value of the voltage and the mass.

A penetration depth of helium in air may be small in general and therefore it is important for this device and not for the antenna arrangement since the device functions to some degree as a matter of principle also without the antenna arrangement, to operate at the frequency recited supra. As stated supra it is essential that the ions are emitted with the predetermined frequency. Namely only with this frequency which is precisely selected so that the ions are reflected at a material corresponding to the frequency the inventive effect can be accomplished. When the ions have other frequencies or another frequency mix they are certainly reflected at other materials. The invention relates to an antenna arrangement to be used with a commercially available functioning detector. The function of the detector is improved by the antenna arrangement according to the invention. As stated supra it is very well possible due to the acceleration voltage to achieve an acceleration with low voltages. The Ion 4He-2 is a cluster with 4 helium atoms that lacks two electrons and that therefore has a very large radius.

### BRIEF DESCRIPTION OF THE DRAWINGS

Other features of the invention can be derived from the subsequent description of the embodiments in combination with the claims, the description and the accompanying drawings. The individual features can be implemented individually or in groups when implementing the invention. The invention is subsequently described based on an advantageous embodiment with reference to drawing figures, wherein:

FIG. 1 illustrates a schematic sectional view of an antenna arrangement in which a printed circuit board is used as a spacer between two magnetic rings;

FIG. 2 illustrates and an antenna arrangement with two magnetic rings and a spacer arranged there between with a pass through bore hole, essentially arranged parallel to the printed circuit board; and

FIG. 3 illustrates a printed circuit board for controlling the antenna.

### DETAILED DESCRIPTION OF THE INVENTION

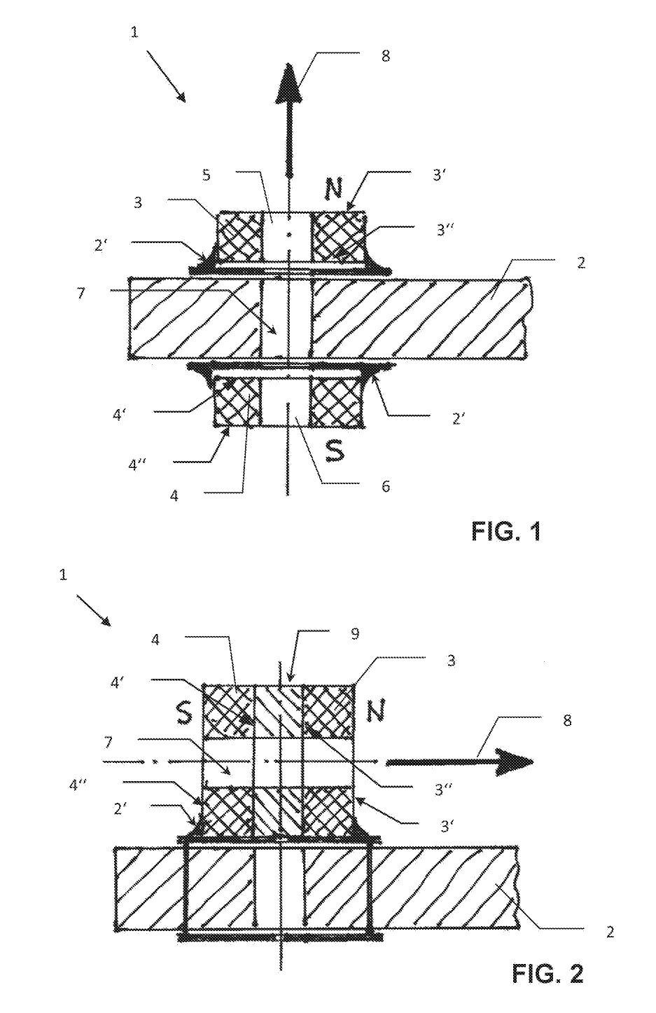

FIG. 1 illustrates an antenna 1 with a magnetic ring 3 and a magnetic ring 4 which are attached with holders 2′ on both sides of a printed circuit board 2. The magnetic rings have a rectangular; thus even square cross section. The lateral magnetic ring surfaces 3′ and 4′ act as a north pole end N and the magnetic rings surfaces 3″ and 4″ act as a south pole S. The holes 5 and 6 of the magnetic rings 3 and 4 are aligned with a bore hole 7 in the printed circuit board 2 and thus form a continuous bore hole. The printed circuit board 2 is used as a spacer between the two magnetic rings 3 and 4 which are arranged so that opposite poles are oriented towards each other. The two magnetic rings 3, 4 respectively form an electrode which is separately connected with an electronic circuit arranged on the printed circuit board 2, wherein the electronic circuit is not illustrated in this figure. The arrow 8 indicates a direction in which the oxygen and nitrogen cations exit from the interior space formed by the holes 5 and 6 and the pass through bore hole 7 as a cation beam. An optional anion beam will move in an opposite direction.

FIG. 2 illustrates a similar arrangement in which identical components are provided with identical reference numerals. In this arrangement both magnetic rings 3 and 4 are arranged on one side of the printed circuit board 2. Between the two magnetic rings 3 and 4 there is a spacer element 9 configured as spacer with a pass through bore hole 7 which is aligned with the holes 5 and 6 in the respective magnetic rings 3 and 4. Thus, the north pole N is arranged on a right side so that the cation beam made from oxygen and/or nitrogen cations moves in a direction of the arrow 8.

The antenna with two magnetic rings illustrated in FIGS. 1 and 2 includes neodym as a magnetic ring material in one embodiment. The magnetic rings 3, 4 have a magnetic strength of 250-300 mT. The spacer 9 and also the printed circuit board 2 have a thickness of 1.5-5 mm. The height of a magnetic ring 3, 4 can be 2-20 mm, the outer diameter can be 6-50 mm and the inner diameter can be 2-10 mm. The antenna can be expanded by additional spacers 9 and magnetic rings 3.

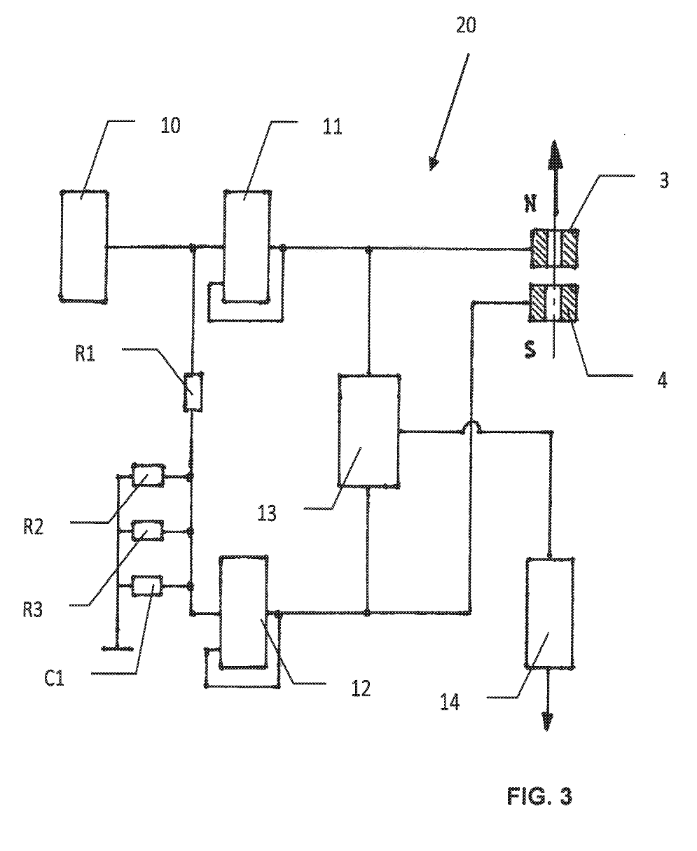

FIG. 3 illustrates a block diagram of an antenna circuit with a triangle generator 10 at which the magnetic rings 3 or 4 are connected in parallel through amplifiers 11 and 12. A differential amplifier 13 is connected between the magnetic rings 3, 4 wherein the differential amplifier runs the obtained signal through an analog-digital converter 14 to an optical and/or in particular acoustic display device. Between the amplifier 12 and the triangle generator 10 there are connectable resistors. In the antenna circuit diagram a resistor R1 is connected in series with the amplifiers 12 wherein parallel resistors R2 and R3 are connected between the resistor and the amplifier 12 the capacitor C1 forming a typical voltage divider circuit for varying voltages.

The triangle generator generates a known triangle or saw tooth signal with a rising flank and a descending flank and a pause between the next triangle signal. Both magnetic rings 3 and 4 are supplied in one embodiment with a saw tooth voltage with an amplitude of 70 mV with a frequency of 149.00 Hz of the saw tooth voltage, wherein the pause is 50% of a period. This frequency can be used for detecting pure water. Through the voltage applied to the magnetic rings 3, 4 oxygen and nitrogen cations and anions are separated from air enveloping the magnetic rings 3 and 4 and arranged in their interior. The cations and anions are accelerated by the arrangement described supra and moved out of the arrangement. As recited supra the arrow 8 indicates the direction of the cations which pass through materials easily due to their small size and which are furthermore accelerated more quickly than the anions moved in opposite direction. When the cations impact pure water like in this embodiment they are reflected. Otherwise they pass through the material. The returning cations can then be detected in the pause of the signal. The detection is performed electronically wherein it is very advantageous for the measurement to follow the measuring process with a head set in order to detect in which direction returning signals occur. The antenna arrangement according to the invention described supra is for example installed in a material detector device that is available at AMPASSMETER GmbH and by which measurements of this type can be performed for finding materials. The detection of different materials is performed with different frequencies which are accessible to a user of a unit of this type.

What is claimed is:

1. An antenna arrangement for a material detecting device for locating objects made from a particular predeterminable material by emitting an ion beam and receiving a returning ion beam that is reflected by the object, wherein properties of the material to be detected cause a reflection of the ion beam, the antenna arrangement comprising:
a printed circuit board at least configured for receiving electronic circuits and components of an antenna circuit; and
an antenna and electrical connection conductors to the antenna,
wherein the antenna emits and receives the ion beam and the antenna circuit generates a transmission signal and processes a return signal,
wherein the antenna includes at least two magnetic rings with a rectangular ring cross section and lateral magnetic ring surfaces thus formed with opposite polarity forming electrodes which are arranged on the printed circuit board by at least one spacer including a bore hole at a distance from one another,
wherein opposite polarities of the magnetic ring surfaces are oriented towards one another and the central bore holes of the magnetic rings in combination with the bore hole in the spacer form a pass through bore hole,
wherein the magnetic rings are connected at the electronic antenna circuit arranged on the printed circuit board,
wherein the antenna circuit applies a repeating triangular or saw tooth signal with a respective pause between the signals to the magnetic rings for generating the ion beam, and
wherein an amplitude and a frequency of the triangle or saw tooth signal with pause is adjustable through the antenna circuit and a detection of different materials is performed with a different frequency or amplitude.

2. The antenna arrangement according to claim 1, wherein the bore hole in the spacer is aligned with the bore holes of the magnetic rings.

3. The antenna arrangement according to claim 1, wherein the spacer for a first magnetic ring and a second magnetic ring is the printed circuit board.

4. The antenna arrangement according to claim 3, wherein the circuit transmits a signal through the magnetic rings and receives a return signal in a transmission pause.

5. The antenna arrangement according to claim 2, whereon the spacer for a first magnetic ring and a second magnetic ring is the printed circuit board.

6. The antenna arrangement according to claim 5, wherein the circuit transmits a signal through the magnetic rings and receives a return signal in a transmission pause.

7. The antenna arrangement according to 1, wherein the circuit transmits a signal through the magnetic rings and receives a return signal in a transmission pause.

8. An antenna arrangement for a material detecting device made from a predetermined material by emitting an emitted signal and receiving a returning signal reflected by predetermined material where properties of the predetermined material cause a reflection of the emitted signal to form the returning signal, the antenna arrangement comprising:
a printed circuit board including an antenna circuit; and
an antenna,
wherein the antenna emits the emitted signal and receives the returning signal,
wherein the antenna circuit generates a transmission signal that is emitted by the antenna as the emitted signal and processes the returning signal from the antenna,
wherein the antenna includes at least two magnetic rings, the at least two magnetic rings each have a rectangular ring cross section and lateral magnetic ring surfaces having opposite polarity forming electrodes on the printed circuit board by at least one spacer including a bore hole at a distance from one another,
wherein opposite polarities of the magnetic ring surfaces are oriented towards one another and bore holes of the magnetic rings in combination with the bore hole in the at least one spacer form a pass through bore hole,
wherein the magnetic rings are connected to the electronic antenna circuit arranged on the printed circuit board,
wherein the antenna circuit applies a repeating triangular or saw tooth signal with a pause between the signals to the magnetic rings, and
wherein an amplitude and a frequency of the triangular or saw tooth signal with the pause is adjustable through the antenna circuit.

9. The antenna arrangement according to claim 8, wherein the bore hole in the at least one spacer is aligned with the bore holes of the at least two magnetic rings.

10. The antenna arrangement according to claim 8,
wherein two adjacent magnetic rings of the at least two magnetic rings sandwiches the printed circuit board, and
wherein the printed circuit board is the spacer for the two adjacent magnetic rings.

11. The antenna arrangement according to claim 8, wherein the returning signal is received while the repeating triangular or saw tooth signal with a pause between the signals is pausing.
